(19) United States
(12) Patent Application Publication
(10) Pub. No.: US 2011/0305852 A1
(43) Pub. Date: Dec. 15, 2011

(54) Electronic circuit substrate

(75) Inventor: Hiroshi SUGAYA, Tokyo (JP)

(73) Assignee: TDK-LAMBDA CORPORATION, Tokyo (JP)

(21) Appl. No.: 13/110,485

(22) Filed: May 18, 2011

(30) Foreign Application Priority Data
May 31, 2010 (JP) 2010-124535

(51) Int. Cl. H05K 1/02

(52) U.S. Cl. 428/33

(57) ABSTRACT

In a method of machining an electronic circuit substrate in which a sub-substrate is attached to a main substrate, an electronic circuit substrate and a method of machining the same in which the sub-substrate can be attached to the main substrate with high degree of accuracy are provided without forming the arcuate portions at corners of the outline of the substrate and corners of an insertion hole even when a router is used for machining substrates.

The sub-substrate 2 is machined using a router as a rotating tool so as to form a notch 5 from a position of a corner where a side surface of a projecting portion and one side of the sub-substrate 2 intersect along one side of the sub-substrate, and the main substrate 10 is machined using the router as a rotating tool so as to have an insertion bore 11 which allows insertion of the sub-substrate and the insertion bore includes a square hole corresponding to the length and the thickness of the projecting portion of the sub-substrate 2 and an incised portion 2 extending from the corner of the square hole along the long side of the square hole.

### BACKGROUND OF THE INVENTION

1. Field of the Invention

The present invention relates to an electronic circuit substrate having a main substrate and a sub-substrate attached to the main substrate, and a method of machining the same and, specifically, to an electronic circuit substrate and a method of machining the same which allow attachment of a sub-substrate to a main substrate with high degree of accuracy.

2. Description of the Related Art

In the related art, when attaching a sub-substrate to a main substrate, a hole for inserting the sub-substrate is formed on the main substrate, an insertion leg portion is provided on the sub-substrate, and the insertion leg portion is inserted into the hole on the main substrate. A pattern for a terminal is provided on the insertion leg portion, so that an electronic circuit substrate is configured by assembling the sub-substrate to the main substrate, then soldering the pattern for the terminal on the insertion leg portion with the pattern of the main substrate.

A structure in which the sub-substrate is attached to the main substrate is disclosed, for example, in Patent Document 1. According to Patent Document 1, a resilient portion is provided on a sub-substrate attaching portion, and the length of a hole portion provided on the main substrate is set so that the mounting portion is pressed against the periphery of the hole portion by resiliency of the resilient portion. Accordingly, inclination of the sub-substrate when attaching the sub-substrate to the main substrate in an upright state is prevented.

Patent Document 2 discloses a composite-type hybrid integrated circuit provided with the sub-substrate having a tongue-shaped insertion leg portion at an end thereof in order to minimize the amount of heat transfer from melted solder to a metallic insulating substrate as the sub-substrate when the sub-substrate is assembled to the main substrate for soldering.

### PRIOR ART DOCUMENTS

### Patent Document

Patent Document 1: JP-A-2003-304044
Patent Document 2: JP-A-5-48262

### SUMMARY OF THE INVENTION

### Problems to be Solved by the Invention

In an electronic circuit substrate configured to provide an insertion bore for inserting the sub-substrate on the main substrate and assemble the sub-substrate on the main substrate, the machined state of the insertion leg portion of the sub-substrate, which is to be assembled into the insertion bore on the main substrate, and the shape and the accuracy of machining of the insertion bore on the main substrate are important. When using a metal mold for machining the outline of the insertion leg portion or the like of the substrate and for machining the insertion bore, the outline of the substrate and corners of the insertion bore can be machined into a right angle or into shapes close thereto, and high degree of machining accuracy can be maintained.

However, in prototyping of substrates on which electronic components are mounted, or small volume manufacturing of the substrates, the outline machining of the substrate and the machining of insertion bores (insertion holes) on the substrate are performed using a router instead of using the metal mold. The router is a tool for rotating a drill at the distal end thereof and machining, the substrate, allows various types of machining, is superior in versatility, and is suitable for prototyping and small-volume manufacturing of the substrates.

FIGS. 8A and 8B are drawings showing an example of machining using the router, in which FIG. 8A shows the machining of the sub-substrate, and FIG. 8B shows a drawing showing an example of machining of the insertion hole on the main substrate. In the machining of the substrate using the router, a drill attached to the distal end of the router is rotated to perform the machining of the substrate. Therefore, even portions which fundamentally should be machined to have corners at a right angle or shapes close thereto such as the corners of the outline of the substrate, the insertion holes may be formed into an arcuate shape due to the round shape of a router drill. For example, as shown in FIG. 8A, corners indicated by dot circles on the outline of a sub-substrate 30 are machined into an arcuate shape. As shown in FIG. 8B, the shape of an insertion hole 41 of a main substrate 40 is not a square hole but an elongated hole, and both end portions shown by dot circles in the insertion hole 41 are also machined into an arcuate shape.

Therefore, there arises a problem such that the sub-substrate cannot be inserted into the main substrate because the arcuate portions become impediments. For example, when the sub-substrate 30 shown in FIG. 8A is attached to the main substrate 40 shown in FIG. 8B via the insertion hole 41, arcuate portions indicated by dot circles of the main substrate 40 and the sub-substrate 30 may interfere with assembly of the sub-substrate 30 or the end surfaces of the insertion hole 41 of the main substrate 40 may be crushed or deformed so that the positional accuracy of attachment of the sub-substrate 30 is lowered.

Even though the length of the insertion hole 41 of the main substrate 40 is increased or the length of the portion where the sub-substrate 30 is to be inserted is adjusted on condition that the arcuate portions are formed, the portions where the main substrate 40 and the sub-substrate 30 are to be attached are combination of arcuate portions. Therefore, contact positions on the arcuate portions are not stable and there arises a problem of positional aberration between the main substrate 40 and the sub-substrate 30.

In this manner, in the machining using the router in the related art, since machining of the outline of the substrate or the insertion hole to have corners at a right angle or shapes close thereto, and there arise problems of deformation of the contact portion between the main substrate and the sub-substrate due to the interference of the arcuate portions at the time of assembly or positional aberration of the sub-substrate.

### Means for Solving the Problem

Accordingly, it is an object of the invention to provide an electronic circuit substrate and a method of machining the same in which a sub-substrate can be attached to a main substrate with high degree of accuracy without forming the arcuate portions at corners of the outline of the substrate and corners of an insertion hole by forming the arcuate portions, which have been formed at corners of the outline of the substrates and at corners of the insertion hole in the related art, at positions other than the corners even when a router is used for machining substrates.

In order to achieve the above-described object, an electronic circuit substrate includes: a main substrate; and a sub-substrate to be attached to the main substrate, and is characterized in that the sub-substrate includes a projecting portion extending from the sub-substrate, an incised portion formed from a position of a corner where a side surface of the projecting portion and one side surface of the sub-substrate intersect along the one side surface of the sub-substrate, the main substrate includes an insertion bore which allows insertion of the sub-substrate, the insertion bore includes a square hole corresponding to the length and the thickness of the projecting portion of the sub-substrate and an incised portion provided at a corner of the square hole.

Preferably, the notch of the sub-substrate is formed into an arcuate shape.

Preferably, the incised portion of the main substrate is formed into an arcuate shape substantially in the vertical direction with respect to the long side of the square hole.

According to the invention, even when the router is used for machining the outline of the sub-substrate and the insertion hole on the main substrate of the electronic circuit substrate, since the arcuate portions which have been formed at the corners of the outline of the substrate and the insertion hole of the substrate in the related art are formed at positions other than the corners so that the portion of the insertion bore of the main substrate coming into contact with the sub-substrate is kept in the linear shape, occurrence of the positional aberration of the sub-substrate can be prevented, so that the sub-substrate can be attached to a predetermined position of the main substrate with high degree of accuracy.

Since the metal mold for machining the outline of the substrate and the insertion hole is not necessary for prototyping the substrate or small volume manufacturing of the substrates, manufacture of the metal mold is not necessary, so that the substrate can be manufactured at a low cost.

### BRIEF DESCRIPTION OF THE DRAWINGS

FIG. 1A is a perspective view of an electronic circuit substrate according to the invention;

FIG. 1B is an enlarged view of a portion surrounded by a dot circle in FIG. 1A;

FIG. 2 is a drawing showing a surface of a sub-substrate of the electronic circuit substrate according to the invention;

FIG. 3 is an enlarged view of a portion near a corner of a projecting portion of the sub-substrate of the electronic circuit substrate according to the invention;

FIG. 4A is a drawing showing a step of forming a notch on the sub-substrate by machining using a router, illustrating a step of moving a machining drill of the router to a position where the projecting portion is to be formed on one side of a sub-substrate body portion and notching the sub-substrate;

FIG. 4B is a drawing showing the step of forming the notch on the sub-substrate by machining using the router, illustrating a step of moving the center of the machining drill of the router on a side surface of the projecting portion to be machined to one side of the sub-substrate body portion and notching the same;

FIG. 4C is a drawing showing the step of forming the notch on the sub-substrate by machining using the router, illustrating a notch machined using the router;

FIG. 5 is a drawing showing a surface of a main substrate of the electronic circuit substrate according to the invention;

FIG. 6 is an enlarged drawing of a portion of an insertion bore of the main substrate of the electronic circuit substrate according to the invention;

FIG. 7A is a drawing showing a step of forming an incised portion on the main substrate by router machining, illustrating a step of moving the machining drill of the router and forming an elongated hole at a position of the main substrate where the insertion bore is to be provided;

FIG. 7B is a drawing showing a step of moving the center of the machining drill of the router from one of side surfaces of the insertion bore upward by an amount corresponding to a half a width h of the insertion bore and downward by an amount corresponding to half the width h of the insertion bore;

FIG. 7C is a drawing showing the incised portion machined by the router;

FIG. 8A is a drawing showing an example of machining using the router, illustrating machining of the sub substrate; and

FIG. 8B is a drawing showing an example of machining using the router, illustrating an example of machining of the insertion hole on the main substrate.

### EXAMPLES FOR CARRYING OUT THE INVENTION

Referring now to the drawings, embodiments for implementing an electronic circuit substrate according to the invention and a method of machining the same will be described. The electronic circuit substrate and the method of machining the same allow attachment of a sub-substrate to a main substrate with high degree of accuracy without forming the arcuate portions at corners of the outline of the substrate and corners of an insertion bore by forming the arcuate portions, which have been formed at corners of the outline of the substrates and at corners of an insertion hole in the related art, at positions other than the corners even when a router is used for machining the substrates.

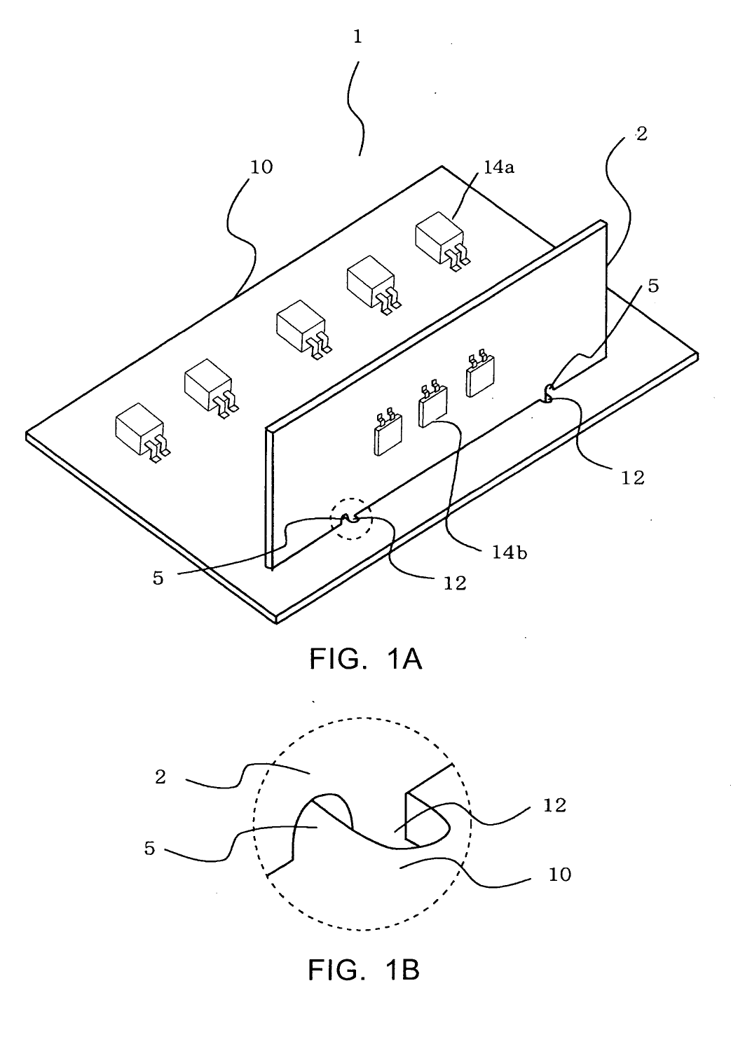

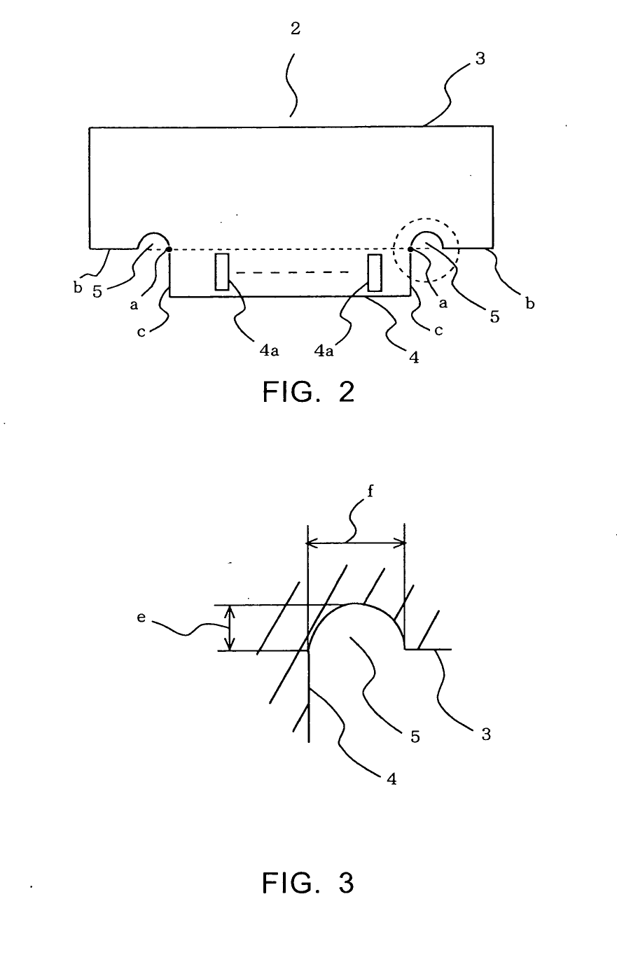

FIG. 1A is a perspective view of an electronic circuit substrate according to the invention, and FIG. 1B is an enlarged view of a portion surrounded by a dot circle in FIG. 1A. FIG. 2 is a drawing showing a surface of the sub-substrate of the electronic circuit substrate according to the invention, and FIG. 3 is an enlarged view of a portion near the corner of a projecting portion of the sub-substrate of the electronic circuit substrate according to the invention.

### [Outline of Electronic Circuit Substrate]

As shown in FIG. 1A, an electronic circuit substrate 1 includes a main substrate 10 and a sub-substrate 2, and has a structure in which the sub-substrate 2 is attached vertically to the main substrate 10. The electronic circuit substrate 1 shown in FIG. 1A includes an electronic component 14a mounted on the main substrate 10, and an electronic component 14b mounted on the sub-substrate 2. Mounting holes of the main substrate 10 for mounting the same to the housing or the like is omitted, and only a configuration of the substrate which is required for description is illustrated. The configuration of the electronic circuit substrate 1 is not limited to the example illustrated in FIGS. 1A and 18.

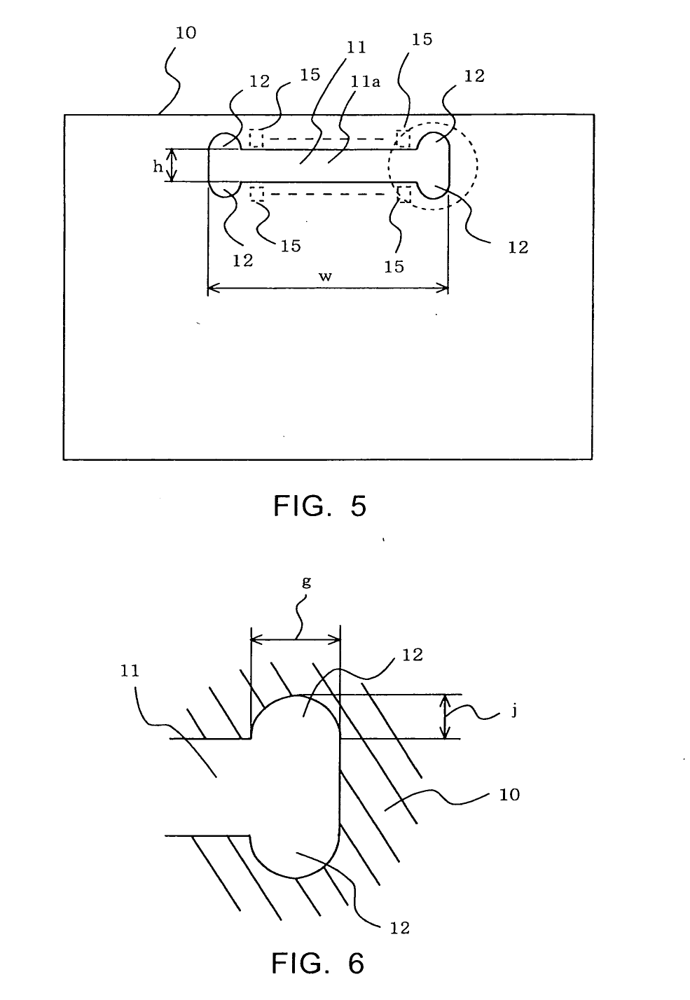

The sub-substrate 2 of the electronic circuit substrate 1 is attached via an insertion bore 11 (shown in FIG. 5) provided on the main substrate 10, and can be electrically connected to the main substrate 10. In other words, it is also possible to insert a projecting portion 4 (shown in FIG. 2) of the sub-substrate 2 into the insertion bore 11 of the main substrate 10, and then solder a land provided at the projecting portion 4 of the sub-substrate 2 with a land provided around the insertion bore 11 of the main substrate 10, so that the main substrate 10 and the sub-substrate 2 are electrically connected.

FIG. 1B is an enlarged view of a portion surrounded by a dot circle in FIG. 1A. As shown in FIG. 1B, the sub-substrate 2 is provided with notches 5 in the vicinity of positions where the sub-substrate 2 and the main substrate 10 are joined and in contact with each other, and the main substrate 10 is provided with an incised portion 12. The notches 5 of the sub-substrate 2 and the incised portions 12 of the main substrate 10 are described later in detail.

### [Notch of Sub-Substrate]

First of all, the sub-substrate of the electronic circuit substrate will be described with reference to FIG. 2 and FIG. 3. The sub-substrate 2 includes electronic components packaged thereon and is to be assembled to the main substrate 10. The sub-substrate 2 is formed of glass epoxy resin or the like as an insulating member. As shown in FIG. 2, the sub-substrate 2 includes a sub-substrate body portion 3 having electronic components packaged thereon and the projecting portion 4 to be joined with the main substrate 10 (shown in FIG. 5). The sub-substrate body portion 3 is provided with wiring patterns (not shown), through holes (not shown), holes for packaging the electronic components (not shown), and lands (not shown) on the front surface and the back surface thereof.

The projecting portion 4 is provided so as to be extended from part of one side of the sub-substrate body portion 3, and has a rectangular shape. As shown in FIG. 2, the projecting portion 4 may be provided with connecting terminals 4a to be electrically connected to the main substrate 10 on one or both surfaces of the projecting portion 4. By the provision of the connecting terminals 4a, the sub-substrate 2 can receive the supply of power source from the main substrate 10 via the connecting terminal 4a of the projecting portion 4, and can transmit and receive signals with respect to the main substrate 10.

As shown in FIG. 2, the sub-substrate 2 includes the arcuate-shaped notches 5 from positions (“a” in FIG. 2) of corners where both end surfaces c of the projecting portion 4 and an imaginary straight line (the straight line indicated by a dot line in FIG. 2) connecting end surfaces b of the sub-substrate body portion 3 having the projecting portion 4 intersect along the end surfaces b of the sub-substrate body portion 3. Both end surfaces c of the projecting portion 4 are formed so as to extend linearly and vertically to the imaginary straight line connecting both ends of one side of the sub-substrate body portion 3. Accordingly, insertion of the projecting portion 4 into the insertion bore 11 (shown in FIG. 5) of the main substrate 10 to the positions indicated by “a” shown in FIG. 2 is ensured.

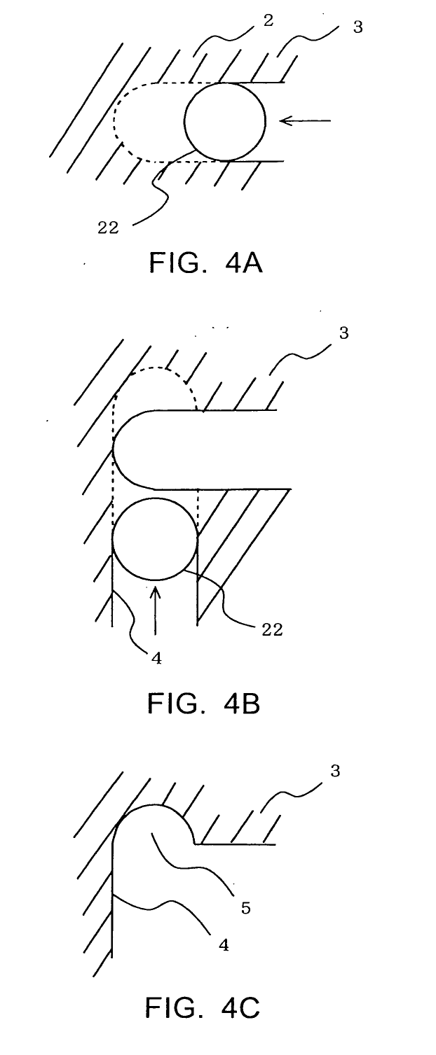

FIG. 3 is an enlarged view of a portion of the sub-substrate shown in FIG. 2 near the corner of the projecting portion indicated by a dot circle. As shown in FIG. 3, the notch 5 has an arcuate shape. The depth e of the notch 5 shown in FIG. 3 is preferably one time or twice the radius of a machining drill 22 (shown in FIG. 4) of a router used for machining the substrate so as to avoid reduction of areas for arrangement of the components on the sub-substrate body portion 3 or for wiring patterns. A notch length f, which is the length of the notch 5 is preferably twice to four times the radius of the machining drill 22 (shown in FIG. 4) of the router used for machining the substrate.

### [Machining of Notches]

Subsequently, a step of forming notches on the sub-substrate using the router will be described. Formation of the notches on the sub-substrate 2 is performed by using the router. In the machining of the sub-substrate using the router, the router or the sub-substrate is fixed. When the router is fixed, the sub-substrate is configured to be movable two-dimensionally in the X-Y direction. When the sub-substrate is fixed, the router is configured to be movable two-dimensionally in the X-Y direction. The router is configured to be movable in the vertical direction (the Z-direction).

FIG. 4 is a drawing showing a step of forming the notches on the sub substrate by the router machining. The hatched portion shown in FIG. 4 is the sub-substrate 2, and a broken line on the sub-substrate shows a route of machining by the router, and a solid line shows a portion machined by the router.

As shown in FIG. 4A, first of all, the machining drill 22 of the router is moved to a position on one side of the sub-substrate body portion 3 where the projecting portion is formed to notch the sub-substrate 2 as indicated by an arrow. Accordingly, the side from the point “b” to “a” of the sub-substrate body portion 3 is formed. Subsequently, as shown in FIG. 4B, the center of the machining drill 22 of the router is moved as indicated by an arrow on the side surface of the projecting portion 4 to be machined to the one side of the sub-substrate body portion 3 to notch the same. Accordingly, the end surface of the projecting portion 4 from the point “c” to the point “a” and the notch 5 shown in FIG. 2 are formed. Accordingly, as shown in FIG. 4C, the notch 5 in an arcuate shape having the same radius of as the machining drill 22 of the router is formed. In the same manner, the other notch 5 is formed on one side of the sub-substrate body portion 3.

In the machining shown in FIG. 4, the depth e of the notch 5 formed by the router (shown in FIG. 3) has the same radius as that of the machining drill 22, and the notch length f of the notch 5 (shown in FIG. 3) has a size as large as double the radius of the machining drill 22. The formation of the notch 5 of the sub-substrate 2 may be achieved by moving the center of the machining drill 22 of the router along the side surface of the projecting portion 4 to be machined to the one side of the sub-substrate body portion 3 and notching the same, and then moving the machining drill 22 to a position where the projecting portion on the one side of the sub-substrate body portion 3 is to be formed and notching the same.

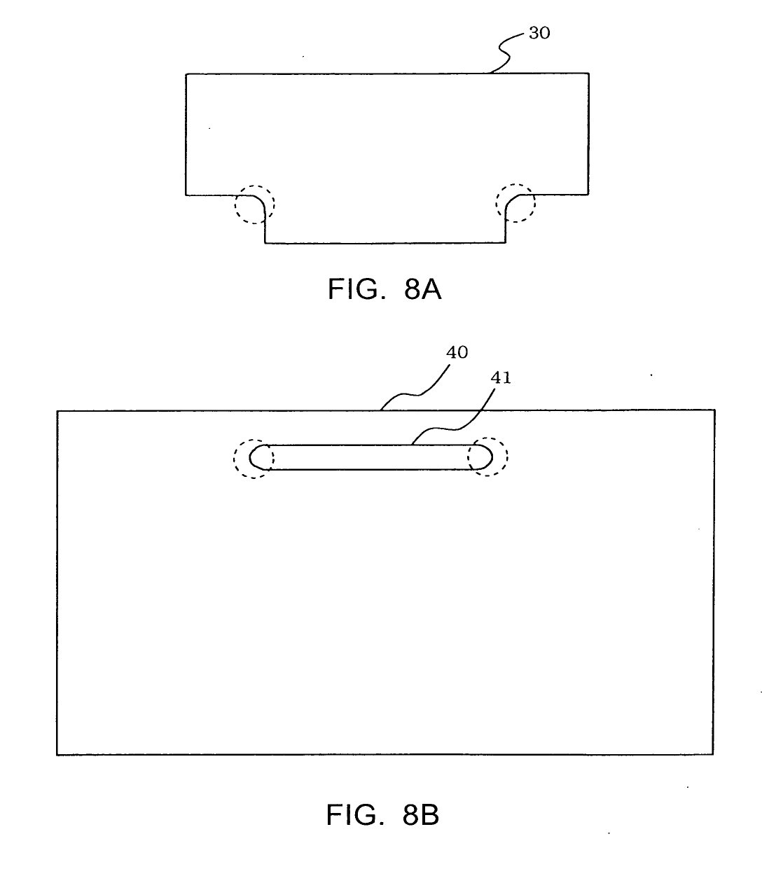

When machining the outline of the substrate using the router in the related art, the arcuate shape of the drill to be used with the router as shown in FIG. 8 is formed even at positions which should be machined to have a corner at a right angle or shapes close thereto, whereby the arcuate portions become impediments, and the position of insertion of the sub-substrate into the main substrate is not stabilized.

With the method of machining according to the invention, the arcuate portions formed at the corners of the projecting portions in the related art are provided at positions other than the corners, so that the necessity of formation of the arcuate portions at the corners is avoided.

Therefore, the sub-substrate of the electronic circuit substrate according to the invention can be formed in such a manner that both ends of the projecting portion extend linearly to the one side of the sub-substrate, the position of insertion of the sub-substrate into the main substrate is stabilized, whereby the position of insertion is always stabilized with reliability.

### [Incised Portion of Main Substrate]

Subsequently, the main substrate of the electronic circuit substrate to which the sub-substrate is to be attached will be described. FIG. 5 is a drawing showing a surface of a main substrate of the electronic circuit substrate according to the invention. FIG. 6 is an enlarged drawing of a portion of an insertion bore of the main substrate of the electronic circuit substrate according to the invention. The main substrate 10 configures the electronic circuit substrate 1 (shown in FIG. 1) with the electronic components and the sub-substrate assembled thereto. The main substrate 10 is formed of glass epoxy resin or the like as the insulating member and, as shown in FIG. 5, the main substrate 10 is provided with the insertion bore 11 for allowing insertion and attachment of the sub-substrate, the through hole (not shown), the wiring pattern (not shown), and the like on the front surface and the back surface thereof. The insertion bore 11 of the main substrate 10 is provided so as to penetrate through the substrate.

As shown in FIG. 5, lands 15 indicated by a dot line to be electrically connected with the sub-substrate may be provided in the periphery of the insertion bore 11 on the back surface of the main substrate 10. By providing the lands 15 on the main substrate 10, supply of power and transmission and reception of signals with respect to the sub-substrate can be performed via the connecting terminals 4a (shown in FIG. 2) provided on the projecting portion 4 of the sub-substrate 2.

As shown in FIG. 5, the insertion bore 11 of the main substrate 10 includes a square hole 11a corresponding to the length and the thickness of the projecting portion 4 of the sub-substrate and the incised portions 12 formed along the long side of the square hole 11a from the corners of the square hole 11a in top view. The square hole 11a has a length w corresponding to the length of the projecting portion 4 of the sub-substrate and a width h corresponding to the thickness of the projecting portion 4. The incised portions 12 are formed from the corners of the square hole 11a into an arcuate shape in the direction substantially vertical to the long side of the square hole 11a.

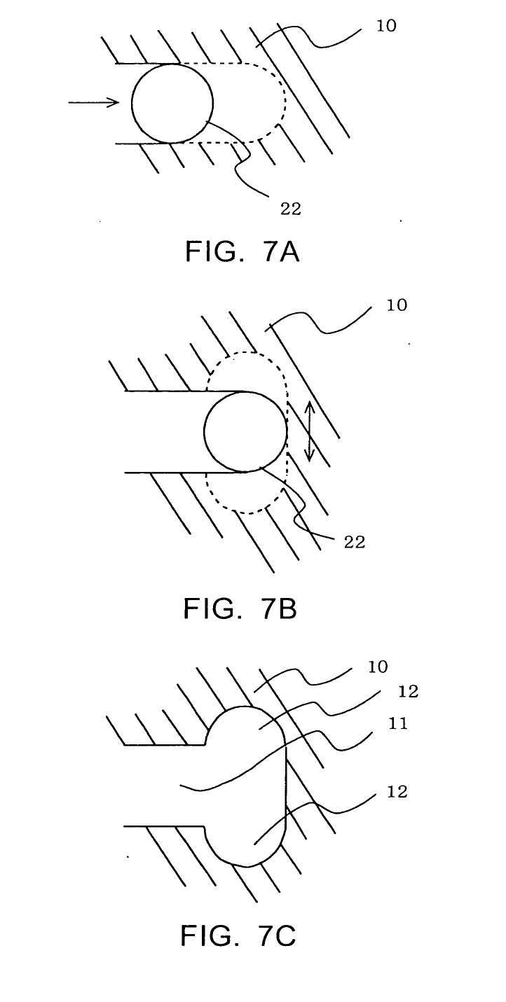

FIG. 6 is an enlarged drawing showing part of the insertion bore indicated by a dot circle on the main substrate shown in FIG. 5. As shown in FIG. 6, the incised portion 12 has an arcuate shape. The depth j of the incised portion 12 shown in FIG. 6 is preferably one time or twice the radius of the machining drill 22 (shown in FIG. 7) of the router used for machining the substrate so as to avoid reduction of areas for arrangement of the components on the main substrate 10 or for wiring patterns. An incision length g, which is the length of the incised portion 12 is preferably twice to four times the radius of the machining drill 22 (shown in FIG. 7) of the router used for machining the substrate.

In this manner, the insertion bore 11 of the main substrate 10 includes the square hole 11a (rectangular shape) and the incised portions 12 formed from the corners of the square hole 11a in the direction substantially vertical to the long side of the square hole 11a having an arcuate shape.

### [Machining of Incised Portion]

Subsequently, a step of forming the incised portions 12 on the main substrate 10 using the router will be described with reference to FIG. 7. The formation of the incised portions 12 on the main substrate 10 is performed using the router. In the machining of the main substrate using the router, the router or the main substrate is fixed. When the router is fixed, the main substrate is configured to be movable two-dimensionally in the X-Y direction. When the main substrate is fixed, the router is configured to be movable two-dimensionally in the X-Y direction. The router is configured to be movable in the vertical direction (the Z-direction).

FIG. 7 is a drawing showing a step of forming the incised portions on the main substrate by the router machining. The hatched portion shown in FIG. 7 is the main substrate 10, and a broken line on the main substrate shows a route of machining by the router, and a solid line shows a portion machined by the router. The machining of the insertion bore 11 on the main substrate 10 using the router is preformed firstly by moving the machining drill 22 of the router in the direction indicated by an arrow as shown in FIG. 7A, and providing an elongated hole corresponding to the length w and the width h shown in FIG. 5. The elongated hole has the similar shape to an insertion hole 41 shown in FIG. 8. The both ends of the insertion bore formed at this time are formed into an arcuate shape. Subsequently, as shown in FIG. 7B, the center of the machining drill 22 of the router is moved from one of the side surfaces of the insertion bore 11 upward by an amount corresponding to a half the width h (shown in FIG. 5) of the insertion bore 11 and downward by an amount corresponding to half the width h as indicated by an arrow. Accordingly, as shown in FIG. 7C, the incised portion 12 in an arcuate shape having the same radius as the machining drill 22 of the router is formed at upper and lower sides of the both ends of the insertion bore 11. In the same manner, the incised portions 12 are formed on the other side surface of the insertion bore 11. Accordingly, the both side end portions of the insertion bores 11 of the main substrate 10 are located between corresponding two incised portions 12 and formed linearly.

In the machining shown in FIG. 7, the depth j of the incised portion 12 formed by the router (shown in FIG. 6) has the same radius as that of the machining drill 22, and the incision length g of the incised portion 12 (shown in FIG. 6) has a size as large as double the radius of the machining drill 22.

When machining the hole of the substrate using the router in the related art, the arcuate shape of the drill to be used with the router is formed even at positions which should be machined to have a corner at a right angle or shapes close thereto, whereby the arcuate portions become impediments, and the position of insertion of the sub-substrate into the main substrate is not stabilized.

With the method of machining according to the invention, the arcuate portions formed at the corners of the insertion bore in the related art are provided at positions other than the corners, so that the necessity of formation of the arcuate portions at the corners is avoided, and the end surfaces of the insertion bore of the main substrate with which the both ends of the projecting portion 4 of the sub-substrate come into contact are formed into a linear shape. Therefore, interference with the sub-substrate is avoided and the position of insertion of the sub-substrate is stabilized, whereby the position of insertion is always stabilized with reliability.

### [Assembly of Electronic Circuit Substrate]

Subsequently, after having machined the sub-substrate and the main-substrate, the electronic components or the like are packaged on the respective substrates. Then, as shown in FIG. 1, the sub-substrate is attached to the main substrate via the insertion bore. After having attached the sub-substrate to the main substrate, both substrates are soldered by performing reflow soldering on the back surface of the main substrate. By performing the soldering, the lands provided around the insertion bore of the main substrate and the terminal patterns on the sub-substrate are joined with solder. Since the projecting portion of the sub-substrate is in tight contact with the insertion bore of the main substrate in the step of soldering, the sub-substrate can maintain a stabilized position without being inclined or displaced. Accordingly, soldering is performed uniformly.

As described above, according to the invention, even when the router is used for machining the outline of the sub-substrate and the insertion bore on the main substrate of the electronic circuit substrate, since the arcuate portions which have been formed at the corners of the outline of the substrate and the insertion hole of the substrate in the related art are formed at positions other than the corners so that the portion of the insertion bore of the main substrate coming into contact with the sub-substrate is kept in the linear shape, occurrence of the positional aberration of the sub-substrate can be prevented, so that the sub-substrate can be attached to a predetermined position of the main substrate with high degree of accuracy.

Since the metal mold for machining the outline of the substrate and the insertion bore is not necessary for prototyping the substrate or small volume manufacturing of the substrates, manufacture of the metal mold is not necessary, so that the substrate can be manufactured at a low cost.

Although the embodiment in which the router is used for machining the sub-substrate and the main substrate of the electronic circuit substrate has been described, the invention is not limited to the router, and other machining apparatuses may be used.

### REFERENCE NUMERAL

1 electronic circuit substrate
2,3 sub-substrate
3 sub-substrate body portion
4 projecting portion
4a connecting terminal
5 notch
10,40 main substrate
11 insertion bore
11a square hole
12 incised portion
15 land
20 solder
22 machining drill
41 insertion hole (insertion bore)

1. An electronic circuit substrate comprising:
a main substrate; and
a sub-substrate to be attached to the main substrate, wherein the sub-substrate includes a projecting portion extending from the sub-substrate, a notch formed from a position of a corner where a side surface of the projecting portion and one side surface of the sub-substrate intersect along the one side surface of the sub-substrate,
the main substrate includes an insertion bore which allows insertion of the sub-substrate,
the insertion bore includes a square hole corresponding to the length and the thickness of the projecting portion of the sub-substrate and an incised portion provided at a corner of the square hole.

2. The electronic circuit substrate according to claim 1, wherein the notch of the sub-substrate is formed into an arcuate shape.

3. The electronic circuit substrate according to claim 1, wherein the incised portion of the main substrate is formed into an arcuate shape substantially in the vertical direction with respect to the long side of the square hole.

4. The electronic circuit substrate according to claim 2, wherein the incised portion of the main substrate is formed into an arcuate shape substantially in the vertical direction with respect to the long side of the square hole.
